(19) United States
(12) Patent Application Publication
(10) Pub. No.: US 2017/0276149 A1
(43) Pub. Date: Sep. 28, 2017

(54) AIRFLOW GENERATOR AND ARRAY OF AIRFLOW GENERATORS

(71) Applicant: GE Aviation Systems LLC, Grand Rapids, MI (US)

(72) Inventors: Michael James DUSSEAU, Walker, MI (US); Stephen Nils HOLEN, Rockford, MI (US)

(21) Appl. No.: 15/504,771

(22) PCT Filed: Aug. 25, 2014
(86) PCT No.: PCT/US2014/052547

§ 371 Date: Feb. 17, 2017

(51) Int. Cl. F04D 33/00; H05K 7/20

(52) U.S. Cl. CPC F04D 33/00; H05K 7/20136

(57) ABSTRACT

An airflow generator and an array of airflow generators are provided for use with an object where each of the airflow generators includes a flexible structure having a first side spaced from a portion of the object to define an air space therebetween and at least one piezoelectric structure located on the flexible structure.

### BACKGROUND

Contemporary high-power-dissipating electronics produce heat that requires thermal management to maintain the electronics at a designed working temperature range. Heat must be removed from the electronic device to improve reliability and prevent premature failure of the electronics. Cooling techniques may be used to minimize hot spots.

### BRIEF DESCRIPTION

In one aspect, an embodiment relates to an airflow generator for use with an object, having a flexible structure having a first side and a second side where the first side of the flexible structure is spaced from a portion of the object to define an air space therebetween and at least one piezoelectric structure located on the flexible structure and wherein the flexible structure forms the air space therebetween without an opposing flexible structure and actuation of the at least one piezoelectric structure results in movement of the flexible structure to increase the volume of the air space therebetween to draw air in and then decrease the volume of the air space therebetween to push out the drawn in air such that the object is cooled by the airflow created by the airflow generator.

In another aspect, an embodiment relates to an array of airflow generators for cooling an object, having multiple airflow generators with each airflow generator, having a flexible structure having a first side and a second side where the first side of the flexible structure is spaced from a portion of the object to define an air space therebetween and at least one piezoelectric structure located on the flexible structure wherein actuation of the piezoelectric structures of the multiple airflow generators results in movement of the flexible structures to increase the volume of the air space therebetween to draw air in and then decrease the volume of the air space therebetween to push out the drawn in air such that the object is cooled by the airflow created by each of the multiple airflow generators.

### BRIEF DESCRIPTION OF THE DRAWINGS

In the drawings:

FIGS. 1A, 1B, and 1C are schematic views of an airflow generator for use with an object according to embodiments described herein.

FIGS. 2A, 2B, and 2C are perspective views of an array of airflow generators according to embodiments described herein.

FIGS. 3A, 3B, and 3C are perspective view of an alternative array of airflow generators according to embodiments described herein.

### DETAILED DESCRIPTION

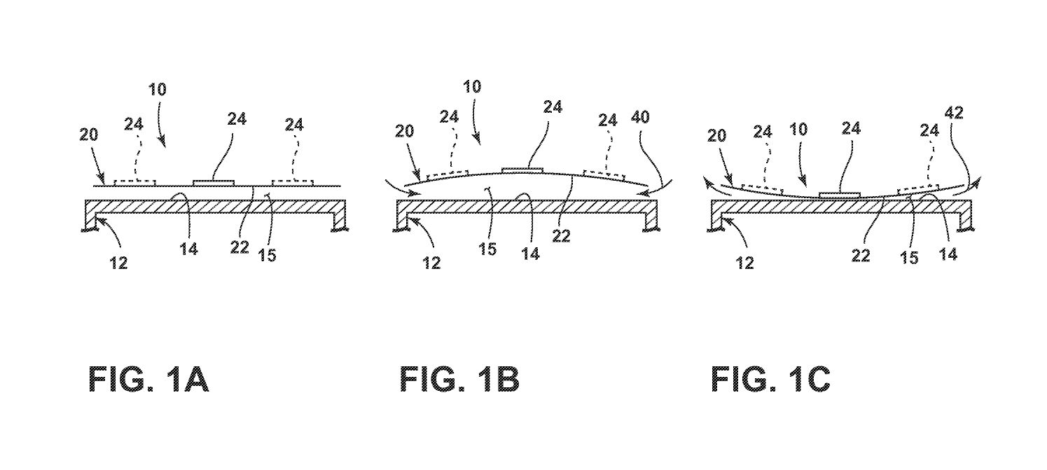

FIG. 1A illustrates an airflow generator 10 for use with an object 12 having a surface 14. The object 12 may include a heat-emitting object and may include any suitable heat-generating element or a heat-exchanging element. A flexible structure 20 having a first side 22 that is spaced from a portion of the object 12 to define an air space therebetween 15. In the illustrated example, the flexible structure 20 has been illustrated as a flexible plate although this need not be the case. The flexible structure 20 may be formed from any suitable flexible material including aluminum, copper, stainless steel, etc. The flexible structure 20 is spaced apart from the object and disposed in a generally confronting relationship with the surface 14 of the object 12. Unlike contemporary airflow generators, the flexible structure 20 forms the air space therebetween 15 without an opposing flexible structure.

A piezoelectric structure 24, for example a piezoelectric crystal, may be located on the flexible structure 20. In the illustrated example, the piezoelectric structure 24 is located at the center of the flexible structure 20 although this need not be the case. While the piezoelectric structure 24 may be located, elsewhere locating it at the center of the flexible structure 20 is believed to increase the deflection of the flexible structure 20. The piezoelectric structure 24 may be operably coupled to a suitable power source through connections (not shown). While at least one single piezoelectric structure 24 may be included on the flexible structure 20, it will be understood that multiple piezoelectric structures may be located on the flexible structure and additional piezoelectric structures 24 have been illustrated in phantom to illustrate this. It will be understood that any number of piezoelectric structures 24 may be included on the flexible structure 20 including a single piezoelectric structure 24. If multiple piezoelectric structures 24 are included, they may be configured to be actuated simultaneously.

During operation, the actuation of the piezoelectric structure 24 results in movement of the flexible structure 20 to increase the volume of the air space therebetween 15 to draw air in and then decrease the volume of the air space therebetween 15 to push out the drawn in air such that the object is cooled by the airflow created by the airflow generator 10. More specifically, when a voltage is applied to the piezoelectric structure 24 the flexible structure 20 is caused to bend such that it is convex as illustrated in FIG. 1B. This deflection causes a decreased partial pressure, which in turn causes air to enter the air space therebetween 15 as illustrated by the arrows 40. When a voltage of opposite polarity is applied, the flexible structure 20 bends in the opposite direction (i.e. concave instead of convex) as illustrated in FIG. 1C. This action decreases the volume of the air space therebetween 15 and causes air to be expelled as illustrated by the arrows 42. In an embodiment, the flexible structure 20 goes past the neutral position (FIG. 1A) to expel a larger volume of air, but it will be understood that any movement of the flexible structure 20 back towards the neutral position would push out some air. The piezoelectric structure 24 is connected to a controllable electric source (not shown) so that an alternating voltage of the desired magnitude and frequency may be applied to the piezoelectric structure 24. The motion of the flexible structure 20 creates a flow of air that may be utilized in cooling hot elements including the object 12. It is contemplated that the flexible structure 20 may overlay a majority of the surface 14 of the object 12 to aid in cooling the entire surface.

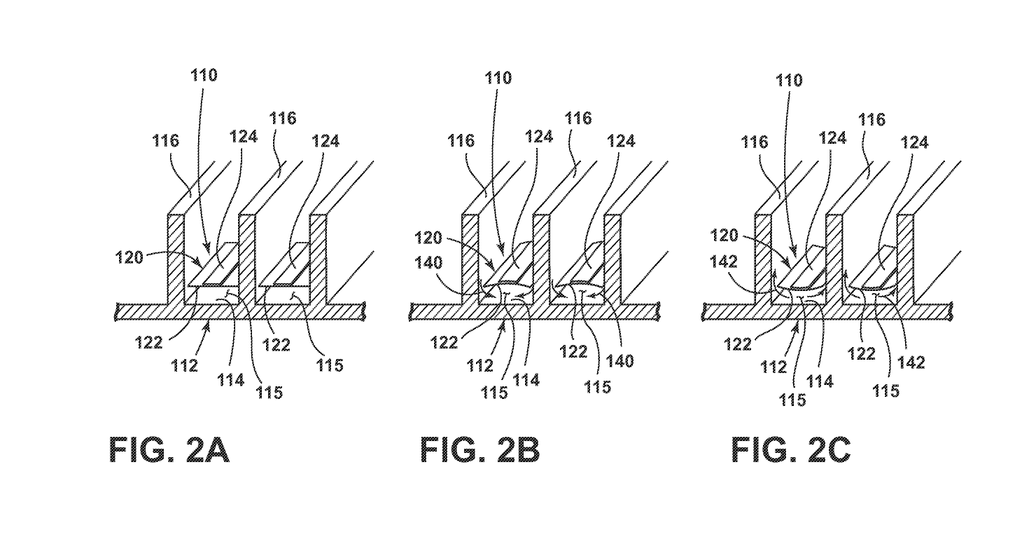

By way of further non-limiting example, FIGS. 2A-2C illustrate an alternative airflow generator 110 according to a an embodiment of the innovation. The airflow generator 110 is similar to the airflow generator 10 previously described and therefore, like parts will be identified with like numerals increased by 100, with it being understood that the description of the like parts of the airflow generator 10 applies to the airflow generator 110, unless otherwise noted.

One difference is that in the illustrated example, the object 112 has been illustrated as a heat-exchanging element in the form of a heat sink having several fins 116. Surfaces 114 are located between the fins 116 of the object 112. Another difference is that an array of airflow generators 110 for cooling the object 112 has been illustrated. More specifically, multiple airflow generators 110 with each airflow generator 110 having a flexible structure 120 and at least one piezoelectric structure 124 located on the flexible structure 120. The multiple airflow generators 110 are spaced from the object 112 to form a number of air space therebetween 115.

While the flexible structure has been illustrated as extending over only a portion of the length of the object 112 it will be understood that the flexible structure 120 may be any suitable size including that it may extend the entire length of the object 112. Further, it will be understood that any number of piezoelectric structures 124 may be included on such flexible structure 120. Further still, the multiple airflow generators 110 may be located end-to-end between fins 116 of the object 112.

The operation of the airflow generators 110 is similar to that of the airflow generator 10 previously described such that actuation of the piezoelectric structures 124 results in movement of the flexible structures 120 to increase the volume of the multiple air space therebetween 115 to draw air in (FIG. 2B) and then decrease the volume of the multiple air space therebetween 115 to push out the drawn in air (FIG. 2C). In this manner, the surfaces 114 of the object 112 are cooled by the airflow created by each of the multiple airflow generators 110.

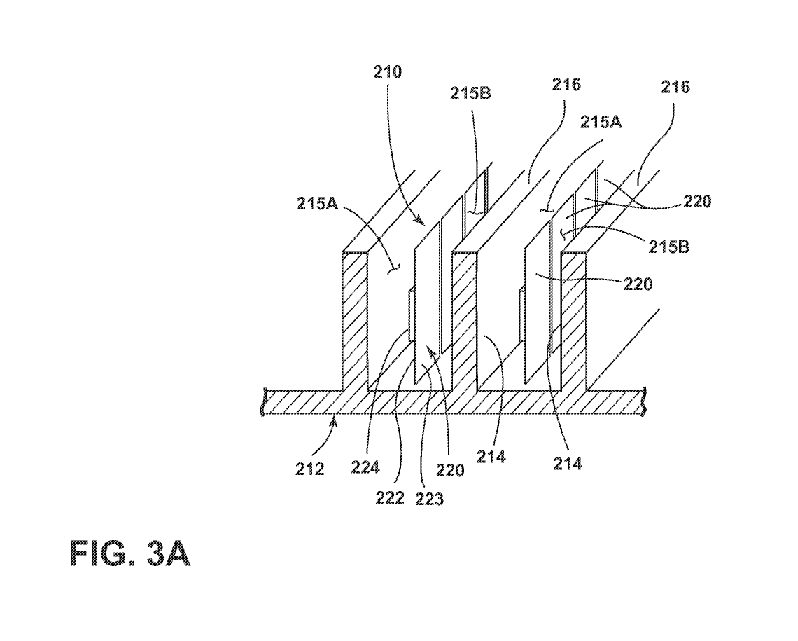

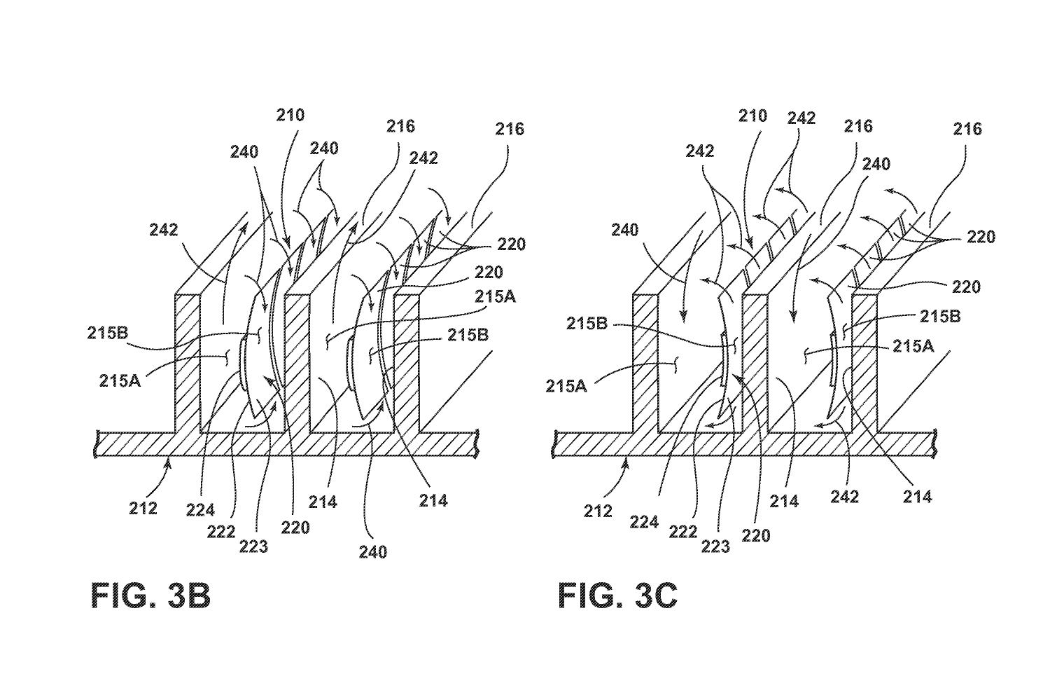

By way of further non-limiting example, FIG. 3 illustrates an alternative airflow generator 210 according to an embodiment of the innovation. The airflow generator 210 is similar to the airflow generator 110 previously described and therefore, like parts will be identified with like numerals increased by 100, with it being understood that the description of the like parts of the airflow generator 110 applies to the airflow generator 210, unless otherwise noted.

One similarity is that an array of airflow generators 210 has been illustrated. One difference is that additional airflow generators 210 have been illustrated between the fins 216 of the object 212. Further, the flexible structures 220 are oriented in a different manner between surfaces 214 created by the fins 216 such that the illustrated multiple airflow generators 210 are spaced from multiple surfaces of the object 212 to define multiple air space therebetween along the multiple surfaces of the object 212. More specifically, two portions of air therebetween are created 215A and 215B. The first side 222 is spaced from a surface 214 to define a first air space therebetween 215A and a second side 223 is spaced from another surface 214 to define a second air space therebetween 215B. While, the multiple airflow generators 210 are illustrated as being located end-to-end between fins 216 of the object 212, this need not be the case.

Instead, a single airflow generator could be used along all or a portion of the object or the airflow generators may be spaced along the length of the object, etc.

During operation, actuation of the piezoelectric structure 224 results in movement of the flexible structure 220 to increase and decrease the volume of the first and second air space therebetween 215A, 215B to draw air in and push out the drawn in air. More specifically, when a first voltage is applied to the piezoelectric structure 224 the flexible structure 220 may flex towards the air space therebetween 215A this may cause air to enter the air space therebetween 215B, as shown by arrows 240, and leave the air space therebetween 215A as shown by arrows 242. When an alternating voltage is applied to the piezoelectric structure 224 the flexible structure 220 may flex towards the air space therebetween 215B and this may cause air to enter the air space therebetween 215A, as shown by arrows 240, and leave the air space therebetween 215B, as shown by arrows 242. The motion of the flexible structure 220 creates a flow of air that may be utilized in cooling multiple surfaces of the object 212. While the multiple airflow generators 210 are illustrated as flexing in the same directions at the same time, it is also contemplated that the airflow generators 210 may be actuated to flex in opposite directions and/or may be actuated at different times including that the airflow generators 210 may be actuated in series or sequentially down a length of the object 212 to move air along the object 212.

In the above embodiments, the airflow generator(s) may be mounted to the object in any suitable manner. By way of non-limiting example, multiple brackets may be used for mounting the flexible structures to the object or a structure near the object. It will be understood that the airflow generators described above may be oriented in any suitable manner with respect to the object such that the airflow generator may produce one or more flows of air that aids in cooling the object. The airflow generators may be utilized with any device that requires thermal management for heat dissipation such as electronic components that require a uniform temperature distribution due to thermal sensitivity. For example, the airflow generators may be used with both airborne, shipboard, and ground based electronics. Further, the above-described embodiments may be spaced from multiple surfaces and portions of an object to cool the multiple surfaces and portions of the object.

The embodiments described above provide a variety of benefits including that such airflow generators solve the thermal management problem of cooling electronic devices with high power dissipations, with local hot spots, or electronic components that require a uniform temperature distribution. The airflow generators described above are easy to manufacture, have low electrical draw, are lightweight, and increase component reliability. The above-described embodiments are also lighter and less expensive than contemporary airflow generators.

To the extent not already described, the different features and structures of the various embodiments may be used in combination with each other as desired. Some features may not be illustrated in all of the embodiments, but may be implemented if desired. Thus, the various features of the different embodiments may be mixed and matched as desired to form new embodiments, whether or not the new embodiments are expressly described. All combinations or permutations of features described herein are covered by this disclosure.

This written description uses examples to disclose the embodiments, including the best implementation, to enable any person skilled in the art to practice the embodiments, including making and using the devices or systems described and performing any incorporated methods presented. The patentable scope of the application is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. An airflow generator for use with an object, comprising:
a flexible structure having a first side spaced from a portion of the object to define an air space therebetween; and
at least one piezoelectric structure located on the flexible structure;
wherein the flexible structure forms the air space therebetween without an opposing flexible structure and actuation of the at least one piezoelectric structure results in movement of the flexible structure to increase a volume of the air space therebetween to draw air in and then decrease the volume of the air space therebetween to push out the drawn in air such that the object is cooled by the airflow created by the airflow generator.

2. The airflow generator of claim 1 wherein multiple piezoelectric structures are located on the flexible structure.

3. The airflow generator of claim 2 wherein the multiple piezoelectric structures are configured to be actuated simultaneously or in sequence.

4. The airflow generator of claim 1 wherein the flexible structure is a plate.

5. The airflow generator of claim 1 wherein the piezoelectric structure is located at the center of flexible structure.

6. The airflow generator of claim 1 wherein the flexible structure overlies a majority of a first surface of the object.

7. The airflow generator of claim 1 wherein a second side is spaced from a portion of an object to define a second air space therebetween and actuation of the at least one piezoelectric structure results in movement of the flexible structure to increase a volume of the second air space therebetween to draw air in and then decrease the volume of the second air space therebetween to push out the drawn in air.

8. An array of airflow generators for cooling an object, comprising:
multiple airflow generators with each airflow generator, comprising:
a flexible structure having a first side and a second side where the first side of the flexible structure is spaced from a portion of the object to define an air space therebetween; and
at least one piezoelectric structure located on the flexible structure;
wherein actuation of the piezoelectric structures of the multiple airflow generators results in movement of the flexible structures to increase a volume of the air space therebetween to draw air in and then decrease the volume of the air space therebetween to push out the drawn in air such that the object is cooled by the airflow created by each of the multiple airflow generators.

9. The array of airflow generators of claim 8 wherein the multiple airflow generators are spaced from multiple portions of a first surface of the object to define multiple air space therebetween along the first surface.

10. The array of airflow generators of claim 9 wherein the multiple airflow generators are configured to be sequentially operated to move air along the object.

11. The array of airflow generators of claim 9 wherein the object is a finned wall and the multiple airflow generators are spaced from the finned wall and are located between fins of the finned wall.

12. The array of airflow generators of claim 11 wherein the multiple airflow generators are located end-to-end between fins of the finned wall.

13. The array of airflow generators of claim 8 wherein at least one of the multiple airflow generators is spaced from multiple surfaces of the object to define multiple air space therebetween along the multiple surfaces of the object.

14. The array of airflow generators of claim 8 wherein at least one of the multiple airflow generators comprises multiple piezoelectric structures included on the flexible structure.
